(19) United States
(12) Patent Application Publication
(10) Pub. No.: US 2011/0239932 A1
(43) Pub. Date: Oct. 6, 2011

(54) Method for reducing defects in epitaxially grown on the group III-nitride materials

(75) Inventors: Edward Yi Chang, Hsinchu (TW); Yuen Yee Wong, Hsinchu (TW)

(73) Assignee: National Chiao Tung University, Hsinchu (TW)

(21) Appl. No.: 12/923,702

(22) Filed: Oct. 5, 2010

(30) Foreign Application Priority Data
Apr. 2, 2010 (TW) 099110277

(51) Int. Cl. C30B 23/02; C30B 23/06

(52) U.S. Cl. 117/108

(57) ABSTRACT

The present invention discloses a method to grow group III-nitride materials on a non-native substrate with much reduced threading dislocation (TD) density and smooth surface by using MBE. The first layer is to suppress the formation of screw TD while the second layer is to bend the propagation of edge TD. After that, the migration enhanced epitaxy (MEE) approach is used to smoothen the second layer surface before a main layer of group III-nitride is growth to the thickness required for different applications. All of these steps are performed in the MBE reactor by carefully control over the arrival rate and sequence of group III atoms and nitrogen radicals onto the sample substrate. By using reflective high energy electron diffraction (RHEED), the change of each layer's surface morphology can be monitored during the growth to achieve the high quality group III-nitride materials.

### BACKGROUND OF THE INVENTION

1. Field of the Invention

The present invention relates to a method to epitaxially grow group III-nitride materials, particularly to a method for reducing defects in epitaxially grown on group III-nitride materials.

2. Description of the Prior Art

In the conventional manufacturing process of epitaxy, due to the growth process is the piling process of individual atom gradually, it will usually produces the edge dislocation, screw dislocation or mixed dislocation, which will causes the enormous defects of the crystalline material, also influences the performance of the material seriously.

In the field of materials science, the crystalline material will produce the phenomenon of dislocation, and it is also called line defect. Usually, it means that there is deformation among crystal lattices along the certain direction in the crystalline solid. If the deformation is more serious, more defects will be produced.

There are two basic types of dislocation, such as the edge dislocation and screw dislocation. In the edge dislocation, the twist of local crystalline lattice is generated along with the end of surplus semi-plane of atom, and the end of surplus semi-plane can be used to define the dislocation line. The screw dislocation can be regarded as the result of shear twist, and its dislocation line passes through the spiral center and atom plane. In the crystalline material, many dislocations possess the edge dislocation and screw dislocation to form the mixed dislocation.

In the prior technical literatures, such as U.S. Pat. No. 5,091,335, only the same group III-nitride material can be formed on the native substrate. And because only single molecular beam epitaxy (MBE) technology is adopted, the convenience of manufacturing process is unable to be achieved. Thus, the convenient principle is violated in actual use, and the method of its use is limited.

In addition, any actual implementation of technology is not disclosed clearly in the paper, including precise temperature and true adjustment ratio. Therefore, the paper can only verify the possibility of theory, but it is difficult to be implemented in accordance with its description. Thus in the practical application, except it is unable to be implemented in actual application aspect, it is also lack of the possibility of industrial application.

Therefore, in order to reduce defects in crystalline material, it is necessary to research and develop innovative epitaxy technology, so as to improve the quality of epitaxy, and reduce the manufacturing time and the manufacturing cost of epitaxy.

### SUMMARY OF THE INVENTION

The present invention relates to a method for reducing defects in epitaxially grown on group III-nitride materials. The molecular beam epitaxy (MBE) technology and the migration enhanced epitaxy (MEE) approach are employed mainly to grow group III-nitride materials on a substrate with much reduced threading dislocation (TD) density and smooth surface.

The present invention provides a non-native substrate firstly. The molecular beam epitaxy (MBE) technology is used to deposit a first layer of group III-nitride with smooth surface morphology on the non-native substrate, which can suppress the formation of screw threading dislocation. Then the molecular beam epitaxy (MBE) technology is used to deposit a second layer of group III-nitride, which can alter the growth direction of edge threading dislocation. Finally, the migration enhanced epitaxy (MEE) approach is used to form a third layer of group III-nitride on the second layer surface. It can enable the reinforcement of diffusion for the adsorbed atom on second layer of group III-nitride, in order to repair the second layer surface.

The difference between the present invention and conventional technology is that the present invention adopts the method without light shield, thus the developing process is not required, and the etching process is not required as well. The high quality group III-nitride materials can be produced at lower cost and higher efficiency.

The present invention can control the speed and flow rate of epitaxy precisely, and monitor the growth of epitaxy synchronously.

Therefore, the advantage and spirit of the invention can be understood further by the following detail description of invention and attached Figures.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A, FIG. 1B, FIG. 1C and FIG. 1D are graphs illustrating the embodiments of the present invention.

FIG. 2 is a graph illustrating the atomic deposition method of the migration enhanced epitaxy approach.

### DESCRIPTION OF THE PREFERRED EMBODIMENT

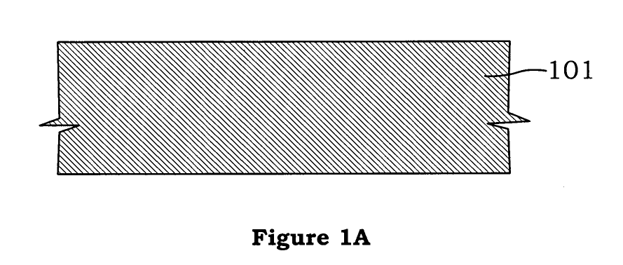

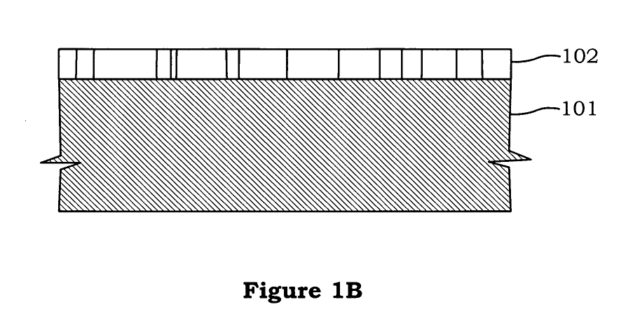

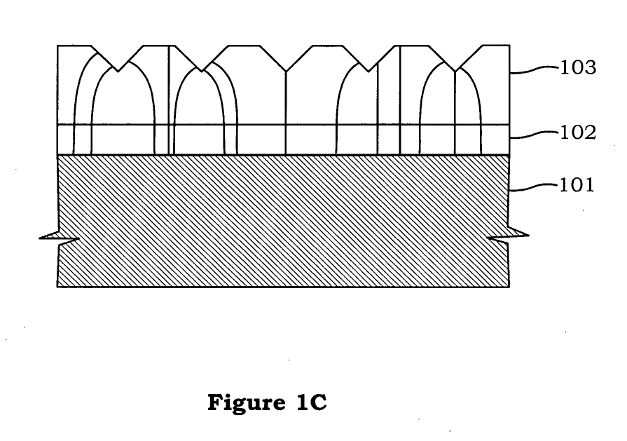

The present invention relates to a method for reducing defects in epitaxially grown on group III-nitride materials (such as gallium nitride) process. The molecular beam epitaxy (MBE) method and the migration enhanced epitaxy (MEE) approach are employed mainly to grow group III-nitride materials on a non-native substrate with much reduced threading dislocation (TD) density and smooth surface. Please refer to FIGS. 1A to 1D, an embodiment for the manufacturing method of the present invention is illustrated, and the detailed explanation is described as follows:

As shown in FIG. 1A, a non-native substrate 101 is provided firstly, such as sapphire substrate, silicon substrate etc. for the following process of the present invention. The non-native substrate stated in the present invention means the substrate different from the gallium nitride substrate, such as the above-mentioned sapphire substrate and silicon substrate etc., which can be used as the non-native substrate in the present invention.

As shown in FIG. 1B, the molecular beam epitaxy (MBE) method is used to deposit a first “group III-nitride layer 102” with smooth surface morphology, such as gallium nitride (GaN) on the non-native substrate 101. When the epitaxial process is carried out, the temperature is controlled at about 740° C., and the deposition ratio of gallium (Ga) and nitrogen (N) is about 1:1, that is the deposition rate of gallium is about equivalent to the deposition rate of nitrogen. At present, the group III-nitride layer 102 formed can suppress the formation of screw threading dislocation.

As shown in FIG. 1C, the molecular beam epitaxy (MBE) method is used to deposit a second “group III-nitride layer 103”on the first “group III-nitride layer 102”. When the epitaxial process is carried out, the temperature is controlled at about 740° C., and the deposition ratio of gallium and nitrogen is about 0.8:1, that is the deposition rate of gallium is less than the deposition rate of nitrogen. Wherein, the surface of the second “group III-nitride layer 103” is full of mesas and trenches, which can alter the growth direction of edge threading dislocation.

As shown in FIG. 1D, the migration enhanced epitaxy (MEE) method is used to form a third “group III-nitride layer 104” on the second “group III-nitride layer 103”. It can enable the reinforcement of diffusion for the adsorbed atom on the second “group III-nitride layer 103”, in order to repair the second “group III-nitride layer 103” surface. Finally, the relevant follow-up manufacturing process is carried on according to the required application fields.

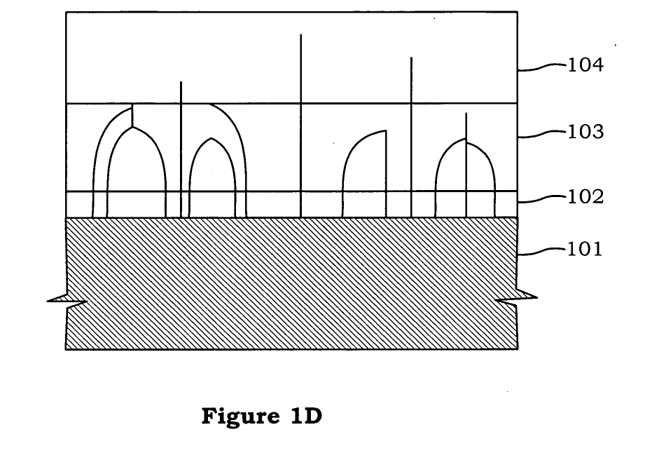

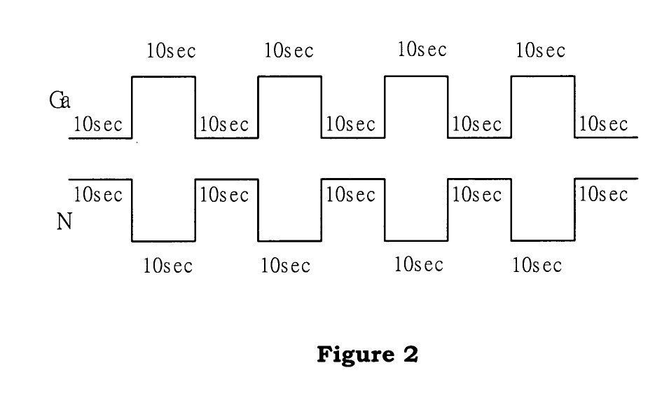

FIG. 2 shows the atomic deposition method of the migration enhanced epitaxy approach. Thus, the previous molecular beam epitaxy technology can control the deposition ratio of group III element (such as gallium atom) and nitrogen atom as well as the growth sequence of every epitaxy layer precisely. The migration enhanced epitaxy approach is carried out by controlling the deposition ratio of group III element and nitrogen atom as well as the time. In the following embodiment of the present invention, the formation of gallium and nitrogen is used as an example to describe the implementation of the migration enhanced epitaxy approach:

The gallium atoms are deposited first for about 10 seconds, and the nitrogen atoms are not deposited at this time. The nitrogen atoms are deposited then for about 10 seconds, and the gallium atoms are not deposited at this time. These two steps form a complete deposition cycle.

In the first half cycle, because no nitrogen atom reaches the substrate, thus the gallium atoms will not crystallize with the nitrogen atoms, and the deposited gallium atoms have sufficient time to move on the surface of second coarse gallium nitride crystal. On the surface of coarse gallium nitride crystal, except the small-area mesas, there are a lot of trenches formed by the steps and kinks. Due to the surface energy of crystal at the step and kink is stronger, thus most gallium atoms will be captured and fixed at these positions, and will not stay on the small mesas.

In the latter half cycle, when the nitrogen atoms are deposited on the surface of gallium nitride crystal, they will react with the gallium atoms captured in the steps and kinks to form the crystal. In the process, due to most gallium atoms will not stay on the flat crystal surface to bond with the nitrogen atoms, the growth rate of crystal at the steps and kinks will be faster than the growth rate of crystal on the flat surface. Thus, after sufficient deposition cycles are carried on by the “migration enhanced epitaxy” approach, the surface of second coarse gallium nitride crystal will be flattened. Certainly, the time of deposition cycle as well as the deposition rate of Ga or nitrogen source can be controlled arbitrarily, thus longer time or shorter time or larger or smaller output amount of Ga and nitrogen can be adjusted. The main purpose is to make the deposition ratio of gallium and nitrogen at 1:1.

When the above-mentioned “migration enhanced epitaxy” approach is employed for growing the material, a movable shutter can be used to control the deposition of different molecule beam on the specimen. When the deposition of a certain material is required, the shutter blocked in front of the material source is opened. When the material provided by the material source is not required, the shutter blocked in front of the material source is closed. Thus, by using the open and close time of shutter as well as the output amount of the material source (can be controlled by the crucible temperature of solid source or the flow rate of gas source), the deposition rate of different materials can be controlled precisely, in order to reach the optimal recovery effect of coarse surface.

By using the reflective high energy electron diffraction (RHEED) technology of molecular beam epitaxy equipment, it is able to observe the immediate change for the material grown on the surface of every layer, in order to control and grow high quality group III-nitride materials effectively. The reflective high energy electron diffraction technology can be used to measure the growth rate of epitaxy and the surface morphology of the material surface. By measuring the variance of diffraction strength with respect the time, it is able to control the accuracy of epitaxy to 0.1 layers of atom. Normally, when the quantum well of gallium nitride is formed, it is necessary to monitor the quality of epitaxy layer by layer, so that its accuracy can reach a layer of atom.

In this invention, the RHEED is more useful in monitoring the change of the morphology of growth material. The RHEED pattern from the smooth surface is composed of streaky lines but will appear as spotty lines from the coarse surface. During the MEE process, the RHEED pattern will be converted from the spotty (or less streaky) lines to streaky lines upon the recovery of the coarse material surface.

The present invention can control the speed and flow rate of epitaxy precisely, and monitor the growth of epitaxy synchronously. The difference between the present invention and traditional technology is that the present invention adopts the method without light shield. Thus, the developing process is not required, and the etching process is not required too. The high quality group III-nitride materials can be produced at lower cost and higher efficiency.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A method for reducing defects in epitaxially grown on group III-nitride materials, comprising:
providing a non-native substrate;
using a molecular beam epitaxy (MBE) method to deposit a first layer of group III-nitride on the non-native substrate for suppressing a formation of screw threading dislocation;
using a molecular beam epitaxy method to deposit a second layer of group III-nitride on the first layer of group III-nitride to alter a growth direction of edge threading dislocation; and
using a migration enhanced epitaxy (MEE) method to form a third layer of group III-nitride on a surface of the second layer of group III-nitride and to repair the surface of the second layer of group III-nitridein order and to form the method for reducing defects in epitaxially grown on the group III-nitride materials.

2. The method according to claim 1, wherein the temperature is controlled at about 740° C. for depositing the first layer of group III-nitride on the non-native substrate by the molecular beam epitaxy method.

3. The method according to claim 1, wherein the deposition ratio of gallium (Ga) and nitrogen (N) comprises about 1:1 for depositing the first layer of group III-nitride on the non-native substrate by the molecular beam epitaxy method.

4. The method according to claim 1, wherein the temperature is controlled at about 740° C. for depositing the second layer of group III-nitride on the first layer of group III-nitride by the molecular beam epitaxy method.

5. The method according to claim 1, wherein the deposition ratio of gallium and nitrogen comprises about 0.8:1 for depositing the second layer of group III-nitride on the first layer of group III-nitride by the molecular beam epitaxy method.

6. A method for reducing defects in epitaxially grown on gallium nitride, comprising:
providing a non-native substrate;
using a molecular beam epitaxy (MBE) method to deposit a first layer of group III-nitride on the non-native substrate for suppressing a formation of screw threading dislocation;
using the molecular beam epitaxy method to deposit a second layer of group III-nitride on the first layer of group III-nitride to alter a growth direction of edge threading dislocation; and
using a migration enhanced epitaxy (MEE) method to form a third layer of group III-nitride on a surface of the second layer of group III-nitride to repair the surface of the second layer of group III-nitride in order to form the method for reducing defects in epitaxially grown on the gallium nitride.

7. The method according to claim 6, wherein the temperature is controlled at about 740° C. for depositing the first layer of gallium nitride on the non-native substrate by the molecular beam epitaxy method.

8. The method according to claim 6, wherein the deposition ratio of gallium (Ga) and nitrogen (N) comprises about 1:1 for depositing the first layer of gallium nitride on the non-native substrate by the molecular beam epitaxy method.

9. The method according to claim 6, wherein the temperature is controlled at about 740° C. for depositing the second layer of gallium nitride on the first layer of gallium nitride by the molecular beam epitaxy method.

10. The method according to claim 6, wherein the deposition ratio of gallium and nitrogen comprises about 0.8:1 for depositing the second layer of gallium nitride on the first layer of gallium nitride by the molecular beam epitaxy method.
